(19) United States
(12) Patent Application Publication
(10) Pub. No.: US 2017/0110643 A1
(43) Pub. Date: Apr. 20, 2017

(54) THERMOELECTRIC COMPOSITE HAVING A THERMOELECTRIC CHARACTERISTIC AND METHOD OF PREPARING SAME

(71) Applicant: INDUSTRY-UNIVERSITY COOPERATION FOUNDATION HANYANG UNIVERSITY ERICA CAMPUS, Ansan-si, Gyeonggi-do (KR)

(72) Inventors: Yong Ho Choa, Asan-Si (KR); Seil Kim, Ansan-si (KR); Yo Min Choi, Ansan-si (KR); Seung Han Ryu, Ansan-si (KR)

(73) Assignee: INDUSTRY-UNIVERSITY COOPERATION FOUNDATION HANYANG UNIVERSITY ERICA CAMPUS, Ansan-si, Gyeonggi-do (KR)

(21) Appl. No.: 15/318,275

(22) PCT Filed: Jun. 4, 2015
(86) PCT No.: PCT/KR2015/005597

§ 371 Date: Dec. 12, 2016

(30) Foreign Application Priority Data
Jun. 13, 2014 (KR) 10-2014-0071801

(51) Int. Cl. H01L 35/16; H01L 35/34

(52) U.S. Cl. CPC H01L 35/16; H01L 35/34

(57) ABSTRACT

The present invention relates to a thermoelectric composite in which a thermoplastic polymer constitutes a matrix, and one or more types of electroconductive materials selected from the group consisting of chalcogen materials and chalcogenides are dispersed at grain boundaries between the thermoplastic polymer particles to form a conductive pathway, wherein an average size of the electroconductive materials is smaller than an average size of the thermoplastic polymer particles, the chalcogen materials are one or more substances selected from the group consisting of sulfur (S), selenium (Se), tellurium (Te), and polonium (Po), the chalcogenides are compounds containing one or more chalcogens selected from the group consisting of S, Se, Te, and Po, and the thermoelectric composite has a thermal conductivity of 0.1 to 0.5 W/m·K. The present invention also relates to a method of preparing the thermoelectric composite. According to the present invention, since a conductive pathway, in which electroconductive materials exhibiting a thermoelectric characteristic are in direct contact with one another, is formed in a thermoplastic polymer matrix and the electroconductive materials are disposed at grain boundaries, which are between thermoplastic polymer particles and are desired locations in the thermoplastic polymer matrix, an optimum thermoelectric characteristic can be attained with a minimum amount of the electroconductive materials. Also, the electroconductive materials having a thermoelectric characteristic in the thermoplastic polymer matrix do not restrict electron transfer, and phonon scattering, which occurs during heat transfer, can be maximized.

### TECHNICAL FIELD

The present invention relates to a thermoelectric composite and a method of preparing the same. More particularly, the present invention relates to a thermoelectric composite and a method of preparing the same, wherein the thermoelectric composite includes a thermoplastic polymer matrix having a conductive pathway in which electroconductive materials exhibiting a thermoelectric characteristic are in direct contact with one another, and is capable of attaining an optimum thermoelectric characteristic with a minimum amount of the electroconductive materials due to a disposition of the electroconductive materials at grain boundaries, which are between thermoplastic polymer particles and are desired locations in the thermoplastic polymer matrix. Also in the same thermoelectric composite, the electroconductive materials having a thermoelectric characteristic in the thermoplastic polymer matrix do not restrict electron transfer, and phonon scattering, which occurs during heat transfer, can be maximized.

### BACKGROUND ART

Methods of preparing a thermoelectric composite have been researched as follows:

First, a method of preparing a composite by mixing polymer emulsion particles and carbon nanotubes in an aqueous solution and then drying the mixture, resulting in high conductivity and low thermal conductivity due to the carbon nanotubes and polymer emulsion, was studied.

Second, a technique of preparing a thermoelectric composite material by attaching PEDOT:PSS (poly(3,4-ethylenedioxythiophene)-poly(styrenesulfonate)) particles between carbon nanotubes, dispersing the complex in an aqueous solution in which polymer emulsion particles are dispersed, and then drying the mixture, also resulting in high conductivity due to PEDOT:PSS, which is a conductive polymer and serves as a junction between the carbon nanotubes and reduces contact resistance, and low thermal conductivity due to use of polymer emulsion particles as a matrix, was studied.

However, in the above studies, only limited types of emulsion particles can be used, and when not successfully dispersed, the particles may cause cohesion or precipitation in an aqueous solution, thus negatively affecting final composite characteristics. Also, since the composites are not prepared by way of melting a thermoplastic polymer through a heat treatment process and then shaping the melt under high pressure, the composites may have a low density and poor mechanical properties accordingly, and a conductive path formed in the composites cannot be easily and accurately located. Moreover, using a large amount of carbon nanotubes to improve composite characteristics leads to increased production costs, and a high carbon nanotube content results in significantly reduced formability, thus making it difficult to take advantage of actual benefits that a composite should provide.

### CITATION LIST

### Non-Patent Literature

[Non-Patent Literature 1]
Choongho Yu et al, Nano Lett. 2008, 8 (12), pp 4428-4432.

[Non-Patent Literature 2]
Dasaroyong Kim et al. ACS Nano vol. 4, No. 1, pp 513-523, 2010.

### DETAILED DESCRIPTION OF THE INVENTION

### Technical Problem

The present invention is directed to providing a thermoelectric composite that includes a thermoplastic polymer matrix having a conductive pathway in which electroconductive materials exhibiting a thermoelectric characteristic are in direct contact with one another, is capable of attaining an optimum thermoelectric characteristic with a minimum amount of the electroconductive materials due to disposition of the electroconductive materials at grain boundaries, which are between thermoplastic polymer particles and are desired locations in the thermoplastic polymer matrix, and is capable of exhibiting an excellent thermoelectric characteristic, electrical conductivity, and heat insulating properties as a composite even with a small amount of electroconductive materials in the thermoplastic polymer matrix. In this case, the electroconductive materials having a thermoelectric characteristic in the thermoplastic polymer matrix do not restrict electron transfer, and phonon scattering, which occurs during heat transfer, can be maximized.

The present invention is directed to providing a method of preparing a thermoelectric composite by inducing disposition of electroconductive materials at an artificially designated location, that is, at an interface of polymer beads, thus resulting in a thermoelectric composite capable of exhibiting thermoelectric characteristics, excellent electrical conductivity, and excellent heat insulating properties while containing a small amount of electroconductive materials.

### Technical Solution

The present invention provides a thermoelectric composite in which a thermoplastic polymer constitutes a matrix, and one or more electroconductive materials selected from the group consisting of chalcogen materials and chalcogenides are dispersed at grain boundaries between the thermoplastic polymer particles to form a conductive pathway. In this case, an average size of the electroconductive materials is smaller than an average size of the thermoplastic polymer particles, the chalcogen materials are one or more substances selected from the group consisting of sulfur (S), selenium (Se), tellurium (Te), and polonium (Po), the chalcogenides are compounds containing one or more chalcogens selected from the group consisting of S, Se, Te, and Po, and the thermoelectric composite has a thermal conductivity of 0.1 to 0.5 W/m·K.

Preferably, the electroconductive materials and the thermoplastic polymer beads are in a volume ratio of 1:3˜30.

The thermoplastic polymer may be one or more materials selected from the group consisting of poly(methyl methacrylate), polyamide, polypropylene, polyester, poly(vinyl chloride), polycarbonate, polyphthalamide, polybutadiene terephthalate, polyethylene terephthalate, polyethylene, polyether ether ketone and polystyrene, and preferably has an average size of 100 nm to 100 μm.

The chalcogenides may be one or more materials selected from the group consisting of CdS, Bi₂Se₃, PbSe, CdSe, PbTeSe, Bi₂Te₃, Sb₂Te₃, PbTe, CdTe, ZnTe, La₃Te₄, AgSbTe₂, Ag₂Te, AgPb₁₈BiTe₂₀, (GeTe)ₓ(AgSbTe₂)₁₋ₓ (x is a real number smaller than 1), AgₓPb₁₈SbTe₂₀ (x is a real number smaller than 1), AgₓPb_{22.5}SbTe₂₀ (x is a real number smaller than 1), SbₓTe₂₀ (x is a real number smaller than 1), and BiₓSb₂₋ₓTe₃ (x is a real number smaller than 2).

The electroconductive materials may take a form of a nanowire, a nanorod, a nanotube, or a fragment.

In addition, the present invention provides a method of preparing a thermoelectric composite, the method including a process of preparing one or more electroconductive materials selected from the group consisting of chalcogen materials and chalcogenides; a process of mixing the electroconductive materials and the thermoplastic polymer beads in a solvent; a process of adsorbing the electroconductive materials onto a surface of the thermoplastic polymer beads by using a difference in surface charge, and drying the mixture of the electroconductive materials and the thermoplastic polymer beads to remove the solvent; and a process of shaping the thermoplastic polymer beads, onto which the electroconductive materials are adsorbed, by a hot pressing method to prepare a thermoelectric composite with a conductive pathway formed by the electroconductive materials dispersed at grain boundaries between the thermoplastic polymer particles. In this case, an average size of the electroconductive materials is smaller than an average size of the thermoplastic polymer particles, the chalcogen materials are one or more substances selected from the group consisting of S, Se, Te, and Po, the chalcogenides are compounds containing one or more chalcogens selected from the group consisting of S, Se, Te, and Po, and the thermoelectric composite has a thermal conductivity of 0.1 to 0.5 W/m·K.

The shaping is preferably performed under a pressure of 10 to 1000 MPa and in a range of temperatures greater than or equal to a glass transition temperature of the thermoplastic polymer beads and, at the same time, less than a melting temperature of the thermoplastic polymer beads so that a contact interface between the thermoplastic polymer beads increases.

Preferably, the electroconductive materials and the thermoplastic polymer beads are mixed in a volume ratio of 1:3˜30.

The thermoplastic polymer beads may contain one or more materials selected from the group consisting of poly(methyl methacrylate), polyamide, polypropylene, polyester, poly(vinyl chloride), polycarbonate, polyphthalamide, polybutadiene terephthalate, polyethylene terephthalate, polyethylene, polyether ether ketone and polystyrene, and preferably have an average size of 100 nm to 100 μm.

The chalcogenides may be one or more materials selected from the group consisting of CdS, Bi₂Se₃, PbSe, CdSe, PbTeSe, Bi₂Te₃, Sb₂Te₃, PbTe, CdTe, ZnTe, La₃Te₄, AgSbTe₂, Ag₂Te, AgPb₁₈BiTe₂₀, (GeTe)ₓ(AgSbTe₂)₁₋ₓ (x is a real number smaller than 1), AgₓPb₁₈SbTe₂₀ (x is a real number smaller than 1), AgₓPb_{22.5}SbTe₂₀ (x is a real number smaller than 1), SbₓTe₂₀ (x is a real number smaller than 1), and BiₓSb₂₋ₓTe₃ (x is a real number smaller than 2).

The electroconductive materials may take a form of a nanowire, a nanorod, a nanotube, or a fragment.

The process of preparing the electroconductive materials may include a process of dissolving one or more oxides selected from the group consisting of oxides based on a chalcogen material and oxides based on a chalcogenide in a solvent; a process of adding a reducing agent to the solvent and performing stirring; and a process of drying the stirred substances to obtain one or more electroconductive materials selected from the group consisting of chalcogen materials and chalcogenides.

The reducing agent may be one or more materials selected from the group consisting of a hydroxylamine (NH₂OH), pyrrole, poly(vinylpyrrolidone) (PVP), polyethylene glycol (PEG), hydrazine hydrate, hydrazine monohydrate, and ascorbic acid.

The solvent may be one or more materials selected from the group consisting of ethylene glycol, diethylene glycol, sodium dodecylbenzenesulfonate (NaDBS), and NaBH₄.

### Advantageous Effects of the Invention

According to the present invention, since a conductive pathway, in which electroconductive materials exhibiting a thermoelectric characteristic are in direct contact with one another, is formed in a thermoplastic polymer matrix and the electroconductive materials are disposed at grain boundaries, which are between thermoplastic polymer particles and are desired locations in the thermoplastic polymer matrix, an optimum thermoelectric characteristic can be attained with a minimum amount of the electroconductive materials. Also, the electroconductive materials having a thermoelectric characteristic in the thermoplastic polymer matrix do not restrict electron transfer, and phonon scattering, which occurs during heat transfer, can be maximized. Moreover, an excellent thermoelectric characteristic, electrical conductivity, and heat insulating properties as a composite can be obtained even with a small amount of electroconductive materials in the thermoplastic polymer matrix.

According to the method of preparing a thermoelectric composite of the present invention, the electroconductive materials are not randomly contained in the thermoplastic polymer matrix, but the disposition thereof at an artificially designated location, that is, at an interface of polymer beads, is induced, thus resulting in a thermoelectric composite capable of exhibiting thermoelectric characteristics, excellent electrical conductivity, and excellent heat insulating properties while containing a small amount of electroconductive materials. When electroconductive materials having a thermoelectric characteristic are disposed in a thermoplastic polymer in an artificial manner, both a good electrical connection and low overall thermal conductivity can be attained due to low thermal conductivity of the polymer itself. When subjected to hot pressing, the thermoplastic polymer beads gain an angular shape due to a high pressure and heat that have been applied, and this can lead to a reduced porosity among the thermoplastic polymer beads (particles) and an increased density, thus resulting in an increased packing density of the thermoelectric composite.

The thermoelectric composite according to the present invention has a thermoelectric characteristic, electrical conductivity, and heat insulating properties, and can be used in fields of materials for heat control components, thermoelectric materials, and the like. An effective formation of a conductive path in the thermoplastic polymer matrix by an electroconductive material results in increased electrical conductivity. Also, due to low inherent thermal conductivity of the thermoplastic polymer matrix, the thermoelectric composite can be applied in the field of composite materials in which low thermal conductivity is required. The thermoelectric composite of the present invention can be used for a product requiring high electrical conductivity and low thermal conductivity. In particular, the thermoelectric composite of the present invention can be applied in the field of thermoelectric materials in which high electrical conductivity and low thermal conductivity are required.

### DESCRIPTION OF THE DRAWINGS

FIG. 1 provides a scanning electron microscopic (SEM) image of tellurium nanowires synthesized according to an exemplary embodiment and an image of the tellurium nanowire powder.

FIG. 2 is a magnified view of the SEM image of FIG. 1.

FIG. 3 provides an SEM image of poly(methyl methacrylate) (PMMA) beads used in an exemplary embodiment and an image of the PMMA bead powder.

FIG. 4 is a magnified view of the SEM image of FIG. 3.

FIGS. 5 to 8 are SEM images of PMMA beads onto which tellurium nanowires are adsorbed.

FIGS. 9 and 10 are cross-sectional SEM images of a thermoelectric composite prepared according to an exemplary embodiment.

FIGS. 11 and 12 are cross-sectional SEM images of a sample shaped out of only tellurium nanowires.

FIG. 13 is a graph showing Seebeck coefficients of thermoelectric composites according to tellurium nanowire content, wherein the thermoelectric composites were prepared according to an exemplary embodiment.

FIG. 14 is a graph showing resistivities of thermoelectric composites according to tellurium nanowire content, wherein the thermoelectric composites were prepared according to an exemplary embodiment.

FIG. 15 is a graph showing power factors of thermoelectric composites according to tellurium nanowire content, wherein the thermoelectric composites were prepared according to an exemplary embodiment.

FIG. 16 is a graph showing carrier concentrations of thermoelectric composites according to tellurium nanowire content, wherein the thermoelectric composites were prepared according to an exemplary embodiment.

FIG. 17 is a graph showing thermal conductivitities of thermoelectric composites prepared according to an exemplary embodiment.

### BEST MODE

A thermoelectric composite according to an exemplary embodiment of the present invention includes a matrix consisting of a thermoplastic polymer, and a conductive pathway formed by one or more electroconductive materials selected from the group consisting of chalcogen materials and chalcogenides that are dispersed at grain boundaries between thermoplastic polymer particles. In this case, an average size of the electroconductive materials is smaller than an average size of the thermoplastic polymer particles, the chalcogen materials are one or more substances selected from the group consisting of sulfur (S), selenium (Se), tellurium (Te), and polonium (Po), the chalcogenides are compounds containing one or more chalcogens selected from the group consisting of S, Se, Te, and Po, and the thermoelectric composite has a thermal conductivity of 0.1 to 0.5 W/m·K.

A method of preparing a thermoelectric composite according to the present invention includes a process of preparing one or more electroconductive materials selected from the group consisting of chalcogen materials and chalcogenides; a process of mixing the electroconductive materials and thermoplastic polymer beads in a solvent; a process of adsorbing the electroconductive materials onto surfaces of the thermoplastic polymer beads by using a difference in surface charge, and drying the mixture of the electroconductive materials and the thermoplastic polymer beads to remove the solvent; and a process of shaping the thermoplastic polymer beads, onto which the electroconductive materials are adsorbed, by a hot pressing method to prepare a thermoelectric composite with a conductive pathway formed by the electroconductive materials dispersed at grain boundaries between the thermoplastic polymer particles. In this case, an average size of the electroconductive materials is smaller than an average size of the thermoplastic polymer particles, the chalcogen materials are one or more substances selected from the group consisting of S, Se, Te, and Po, the chalcogenides are compounds containing one or more chalcogens selected from the group consisting of S, Se, Te, and Po, and the thermoelectric composite has a thermal conductivity of 0.1 to 0.5 W/m·K.

### Mode of the Invention

Hereinafter, exemplary embodiments according to the present invention will be described in detail with reference to accompanying drawings. However, the following exemplary embodiments are provided for better understanding of those skilled in the art. Also, the present invention may be embodied in different forms, and should not be limited to the embodiments set forth herein.

Hereinafter, the term “nano” refers to a size in a nanometer (nm) scale, which ranges from 1 to 1,000 nm “Nanowire” refers to a wire having a size of 1 to 1,000 nm, “nanorod” refers to a rod having a diameter ranging from 1 to 1,000 nm, and “nanotube” refers to a tube having a diameter ranging from 1 to 1,000 nm.

The present invention provides a thermoelectric composite having a thermoelectric characteristic and a method of preparing the same.

When a composite is prepared by dispersing a significant amount of a thermoelectric filler in a polymer in pursuit of a good thermoelectric property, the following problems may occur.

First, using a large amount of carbon nanotubes to improve composite characteristics leads to increased production costs. Second, a high carbon nanotube content results in significantly reduced formability, thus making it difficult to take advantage of actual benefits that a composite should provide. Therefore, to ensure fluidity for easy shaping and optimum composite material properties, it is preferred that the development of a polymer composite material is directed to attaining an optimum thermoelectric characteristic with a minimum amount of a thermoelectric filler.

In order to obtain an optimum thermoelectric characteristic with a minimum amount of a thermoelectric filler, the thermoelectric filler having a thermoelectric characteristic in the polymer matrix should not restrict electron transfer, and phonon scattering, which occurs during heat transfer, should be maximized. Also, a conductive pathway in which the thermoelectric filler particles are in direct contact with one another should be formed in the polymer matrix, requiring the electroconductive thermoelectric filler particles to be disposed at desired locations in the polymer matrix.

However, a technique of preparing a thermoelectric composite by randomly mixing a (liquid) polymer is disadvantageous in that the disposition of thermoelectric filler particles at desired locations is difficult to implement, and a large amount of a thermoelectric filler is required for the disposition of the thermoelectric filler particles in a polymer matrix. Therefore, to develop a thermoelectric composite having an optimum thermoelectric characteristic with a minimum amount of a thermoelectric filler, an effective way of forming a conductive pathway of thermoelectric filler particles in a polymer matrix should be established.

The present invention is directed to preparing a thermoelectric composite expressing a thermoelectric characteristic by disposing thermoelectric filler particles at desired locations in a polymer matrix in an easy way. To prepare a thermoelectric composite containing thermoelectric filler particles disposed at desired locations, a thermoplastic polymer is used as a matrix, and one or more electroconductive materials selected from the group consisting of chalcogen materials and chalcogenides having a thermoelectric characteristic are used as a filler in the present invention.

A thermoelectric composite according to an exemplary embodiment of the present invention includes a matrix consisting of a thermoplastic polymer, and a conductive pathway formed by one or more electroconductive materials selected from the group consisting of chalcogen materials and chalcogenides that are dispersed at grain boundaries between the thermoplastic polymer particles. The thermoelectric composite has a thermal conductivity of 0.1 to 0.5 W/m·K.

The electroconductive materials and the thermoplastic polymer beads may be in a volume ratio of 1:3˜30.

The electroconductive materials are one or more materials selected from the group consisting of chalcogen materials and chalcogenides. The electroconductive materials may take a form of a nanowire, a nanorod, a nanotube, a fragment, or the like. An average size of the electroconductive materials is smaller than an average size of the thermoplastic polymer particles.

The chalcogen materials are one or more substances selected from the group consisting of S, Se, Te, and Po. The chalcogen materials may take a form of a nanowire, a nanorod, a nanotube, a fragment, or the like, and examples of such chalcogen materials include a tellurium nanowire, a selenium nanowire, and the like. When the chalcogen materials are nanowires, nanorods, or the like, an average size of the electroconductive materials refer to an average length of the nanowires, nanorods, or the like.

The chalcogenides are compounds containing one or more chalcogens selected from the group consisting of S, Se, Te, and Po. A chalcogenide is a binary or higher order compound that contains one or more chalcogen materials selected from the group consisting of group 16 elements (except for oxygen) in the Periodic Table, which are S, Se, Te, and Po. Examples of such chalcogenides include CdS, Bi₂Se₃, PbSe, CdSe, PbTeSe, Bi₂Te₃, Sb₂Te₃, PbTe, CdTe, ZnTe, La₃Te₄, AgSbTe₂, Ag₂Te, AgPb₁₈BiTe₂₀, (GeTe)ₓ(AgSbTe₂)₁₋ₓ (x is a real number smaller than 1), AgₓPb₁₈SbTe₂₀ (x is a real number smaller than 1), AgₓPb_{22.5}SbTe₂₀ (x is a real number smaller than 1), SbₓTe₂₀ (x is a real number smaller than 1), BiₓSb₂₋ₓTe₃ (x is a real number smaller than 2), and a mixture thereof. The chalcogenides may take a form of a nanowire, a nanorod, a nanotube, a fragment, or the like.

The thermoplastic polymer may be one or more materials selected from the group consisting of poly(methyl methacrylate), polyamide, polypropylene, polyester, poly(vinyl chloride), polycarbonate, polyphthalamide, polybutadiene terephthalate, polyethylene terephthalate, polyethylene, polyether ether ketone and polystyrene, and preferably has an average size of 100 nm to 100 μm.

The thermoelectric composite of the present invention is prepared by mixing electroconductive materials having a thermoelectric characteristic and thermoplastic polymer beads having an insulating characteristic in a solvent for dispersion, subsequently drying the substances to obtain a polymer bead powder onto which the electroconductive materials are adsorbed, and then shaping the powder by a hot pressing method.

The method of preparing a thermoelectric composite according to an exemplary embodiment of the present invention includes a process of preparing one or more electroconductive materials selected from the group consisting of chalcogen materials and chalcogenides; a process of mixing the electroconductive materials and the thermoplastic polymer beads in a solvent; a process of adsorbing the electroconductive materials onto a surface of the thermoplastic polymer beads by using a difference in surface charge, and drying the mixture of the electroconductive materials and the thermoplastic polymer beads to remove the solvent; and a process of shaping the thermoplastic polymer beads, onto which the electroconductive materials are adsorbed, by a hot pressing method to prepare a thermoelectric composite with a conductive pathway formed by the electroconductive materials dispersed at grain boundaries between the thermoplastic polymer particles. In this case, an average size of the electroconductive materials is smaller than an average size of the thermoplastic polymer particles, the chalcogen materials are one or more substances selected from the group consisting of S, Se, Te, and Po, the chalcogenides are compounds containing one or more chalcogens selected from the group consisting of S, Se, Te, and Po, and the thermoelectric composite has a thermal conductivity of 0.1 to 0.5 W/m·K.

Hereinafter, the method of preparing a thermoelectric composite according to an exemplary embodiment will be described in more detail.

One or more electroconductive materials selected from the group consisting of chalcogen materials and chalcogenides are prepared.

The electroconductive materials may take a form of a nanowire, a nanorod, a nanotube, a fragment, or the like.

The chalcogen materials are one or more materials selected from the group consisting of S, Se, Te, and Po. The chalcogen materials may take a form of a nanowire, a nanorod, a nanotube, a fragment, or the like, and examples of such chalcogen materials include a tellurium nanowire, a selenium nanowire, and the like.

The chalcogenides are binary or higher order compounds that contain one or more chalcogen materials selected from the group consisting of group 16 elements (except for oxygen) in the Periodic Table, which are S, Se, Te, and Po. Examples of such chalcogenides include CdS, Bi₂Se₃, PbSe, CdSe, PbTeSe, Bi₂Te₃, Sb₂Te₃, PbTe, CdTe, ZnTe, La₃Te₄, AgSbTe₂, Ag₂Te, AgPb₁₈BiTe₂₀, (GeTe)ₓ(AgSbTe₂)₁₋ₓ (x is a real number smaller than 1), AgₓPb₁₈SbTe₂₀ (x is a real number smaller than 1), AgₓPb_{22.5}SbTe₂₀ (x is a real number smaller than 1), SbₓTe₂₀ (x is a real number smaller than 1), BiₓSb₂₋ₓTe₃ (x is a real number smaller than 2), and a mixture thereof. The chalcogenides may take a form of a nanowire, a nanorod, a nanotube, a fragment, or the like.

The one or more electroconductive materials selected from the group consisting of the chalcogen materials and chalcogenides may be synthesized by a solvothermal method.

For example, the one or more electroconductive materials selected from the group consisting of the chalcogen materials and chalcogenides may be obtained by dissolving one or more oxides selected from the group consisting of oxides based on a chalcogen material or a chalcogenide in a solvent, adding a reducing agent in the solvent, stirring the mixture, and then drying the stirred substances.

The oxides based on a chalcogen material are oxides containing one or more materials selected from the group consisting of S, Se, Te, and Po, and examples thereof include a tellurium oxide.

The oxides based on a chalcogenide is a material formed as a result of oxidization of a compound containing one or more chalcogens selected from the group consisting of S, Se, Te, and Po, and examples thereof include CdTeO₃.

It is preferred that the one or more oxides selected from the group consisting of oxides based on a chalcogen material or a chalcogenide are dissolved at a temperature of about 150 to 200° C. while stirring for a sufficient time (e.g., ten minutes to 48 hours). The stirring is preferably performed at a rotational speed of about 10 to 500 rpm.

The solvent may be one or more materials selected from the group consisting of ethylene glycol, diethylene glycol, sodium dodecylbenzenesulfonate (NaDBS), and NaBH₄.

The reducing agent may be one or more materials selected from the group consisting of a hydroxylamine (NH₂OH) solution, pyrrole, poly(vinylpyrrolidone) (PVP), polyethylene glycol (PEG), hydrazine hydrate, hydrazine monohydrate, and ascorbic acid. The reducing agent is preferably added slowly to the solvent by using a micropipette or the like.

The reducing agent is added to the solvent, and then the mixture is stirred for a sufficient time (e.g., ten minutes to 48 hours). The stirring is preferably performed at a rotational speed of about 10 to 500 rpm.

When the substances resulting from adding the reducing agent and then stirring are dried, one or more electroconductive materials selected from the group consisting of chalcogen materials and chalcogenides can be obtained. Preferably, the drying is performed for a sufficient time (e.g., ten minutes to 48 hours) in a vacuum oven at a temperature of about 40 to 100° C.

The electroconductive materials and the thermoplastic polymer beads are added to the solvent. The electroconductive materials and the thermoplastic polymer beads are preferably mixed in a volume ratio of 1:3˜30. The electroconductive materials having an average size smaller than an average size of the thermoplastic polymer beads are used.

The thermoplastic polymer beads may contain one or more materials selected from the group consisting of poly(methyl methacrylate), polyamide, polypropylene, polyester, poly(vinyl chloride), polycarbonate, polyphthalamide, polybutadiene terephthalate, polyethylene terephthalate, polyethylene, polyether ether ketone and polystyrene, and preferably have an average size of 100 nm to 100 μm.

The solvent may be an alcohol-based solvent such as isopropyl alcohol, ethanol, and methanol, and is not limited to a particular type of a solvent as long as it does not chemically react with the electroconductive materials and the thermoplastic polymer beads.

The electroconductive materials and the thermoplastic polymer beads are preferably mixed for a sufficient time (e.g., ten minutes to 48 hours) while stirring. Preferably, the stirring is performed at a rotational speed of about 100 to 800 rpm.

The electroconductive materials are adsorbed onto (i.e. provide a coating on) a surface of the thermoplastic polymer beads by using a difference in surface charge, and the mixture of the electroconductive materials and the thermoplastic polymer beads is dried to remove the solvent. When the mixture of the electroconductive materials and the thermoplastic polymer beads is dried, the electroconductive materials are adsorbed onto (i.e. provide a coating on) a surface of the thermoplastic polymer beads due to a difference in surface charge, and the solvent is removed, thus resulting in a thermoplastic polymer bead powder containing the electroconductive material coating. Preferably, the drying is performed for a sufficient time (e.g., ten minutes to 48 hours) in a vacuum oven at a temperature of about 40 to 100° C.

The thermoplastic polymer beads that the electroconductive materials are adsorbed onto (i.e. provide a coating on) is shaped by a hot pressing method to prepare a thermoelectric composite containing a conductive pathway formed by the electroconductive materials dispersed at grain boundaries between the thermoplastic polymer particles.

The shaping is preferably performed under a pressure of 10 to 1000 MPa and in a range of temperatures greater than or equal to a glass transition temperature of the thermoplastic polymer beads and, at the same time, less than a melting temperature of the thermoplastic polymer beads so that a contact interface between the thermoplastic polymer beads increases.

When subjected to hot pressing, the thermoplastic polymer beads attain an angular shape due to a high pressure and heat that have been applied, and this can lead to a reduced porosity among the thermoplastic polymer beads (particles) and an increased density, thus resulting in an increased packing density of the thermoelectric composite.

According to the method of preparing a thermoelectric composite of the present invention, the electroconductive materials are not randomly contained in the thermoplastic polymer matrix, but the disposition thereof at an artificially designated location, that is, at an interface of polymer beads, is induced, thus resulting in a thermoelectric composite capable of exhibiting thermoelectric characteristics, excellent electrical conductivity, and excellent heat insulating properties while containing a small amount of electroconductive materials. When electroconductive materials having a thermoelectric characteristic are disposed in a thermoplastic polymer in an artificial manner, both a good electrical connection and low overall thermal conductivity can be attained due to low thermal conductivity of the polymer itself.

The thermoelectric composite according to the present invention has a thermoelectric characteristic, electrical conductivity, and heat insulating properties, and can be used in fields of materials for heat control components, thermoelectric materials, and the like. An effective formation of a conductive path in the thermoplastic polymer matrix by an electroconductive material results in increased electrical conductivity. Also, due to low inherent thermal conductivity of the thermoplastic polymer matrix, the thermoelectric composite can be applied in the field of composite materials in which low thermal conductivity is required. The thermoelectric composite of the present invention can be used for a product requiring high electrical conductivity and low thermal conductivity. In particular, the thermoelectric composite of the present invention can be applied in the field of thermoelectric materials in which high electrical conductivity and low thermal conductivity are required.

Hereinafter, exemplary embodiments of the present invention will be provided in detail. However, the embodiments set forth herein do not limit the present invention.

A thermoelectric composite according to an exemplary embodiment of the present invention was prepared as follows: tellurium nanowires having a diameter of about 200 nm were synthesized by a solvothermal method, the tellurium nanowires that had been synthesized were uniformly adsorbed onto a surface of thermoplastic polymer beads using a difference in surface charge to prepare a composite powder, and the polymer bead powder containing a tellurium nanowire coating was shaped by hot pressing to prepare the thermoelectric composite. Such a method of preparing a thermoelectric composite can produce a maximum effect even with a small amount of electroconductive materials in a differentiated manner from conventional methods of preparing a composite material. Since the thermoelectric composite prepared as thus contains a conductive pathway formed by electroconductive materials in a thermoplastic polymer matrix, the thermoelectric composite can exhibit a thermoelectric characteristic, electrical conductivity, and heat insulating properties even with a small amount of electroconductive materials.

Hereinafter, an exemplary preparation of a thermoelectric composite according to an exemplary embodiment will be described in more detail.

Tellurium nanowires were synthesized using a solvothermal method. To synthesize the tellurium nanowires, 500 ml of ethylene glycol (ethylene glycol anhydride 99.8%) and 10 g of tellurium dioxide (99.99%) were put in a 1000 ml volumetric flask, and stirring was performed at 180° C. for two hours.

After about two hours of stirring, the tellurium dioxide was dissolved and the solution turned transparent. At this time, 20 ml of a hydroxylamine solution (50 wt % in H₂O) was added to the solution using a micropipette, and the solution in the volumetric flask gradually turned from transparent to dark gray, indicating a synthesis of tellurium nanowires as a result of the reduction of the tellurium dioxide.

Upon completing the addition of the hydroxylamine solution, stirring was again performed for about two hours, and the mixture was cooled at room temperature.

The mixture was washed with deionized water five times or more to remove polymer components. Then, the mixture was put in a vacuum oven and was dried at 80° C. for six hours to obtain tellurium nanowires having a diameter of about 200 nm.

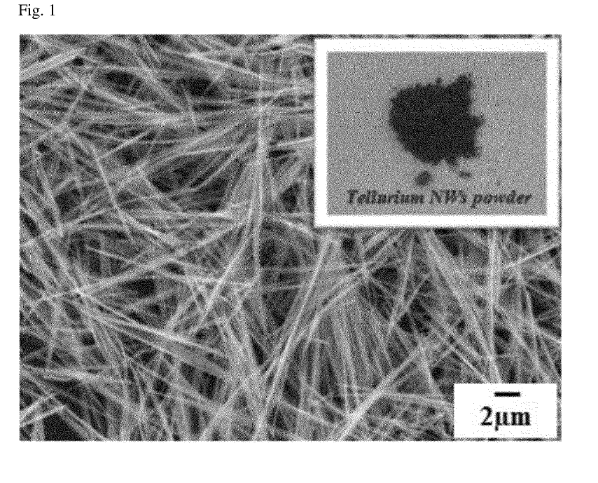

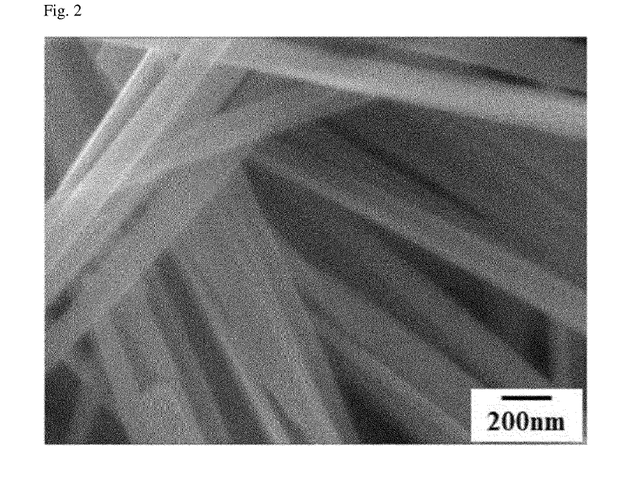

FIG. 1 provides a scanning electron microscopic (SEM) image of tellurium nanowires synthesized according to an exemplary embodiment and an image of the tellurium nanowire powder, and FIG. 2 is a magnified view of the SEM image of FIG. 1.

Using the tellurium nanowires that have been synthesized, a thermoelectric composite was prepared.

To prepare the thermoelectric composite, first, the tellurium nanowires were added to an alcohol-based solvent, isopropyl alcohol, and sonication was performed for about 30 minutes.

Poly(methyl methacrylate) (PMMA) beads, which are thermoplastic polymer beads, were put in the isopropyl alcohol in which the tellurium nanowires were dispersed, and stirring was performed at a high speed of about 400 rpm for three hours.

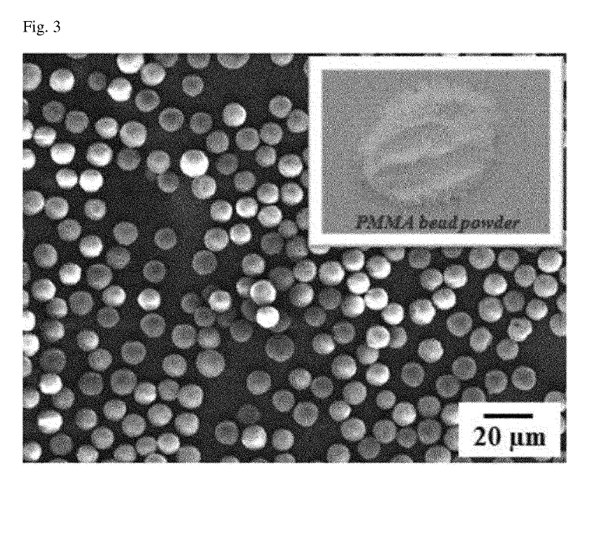

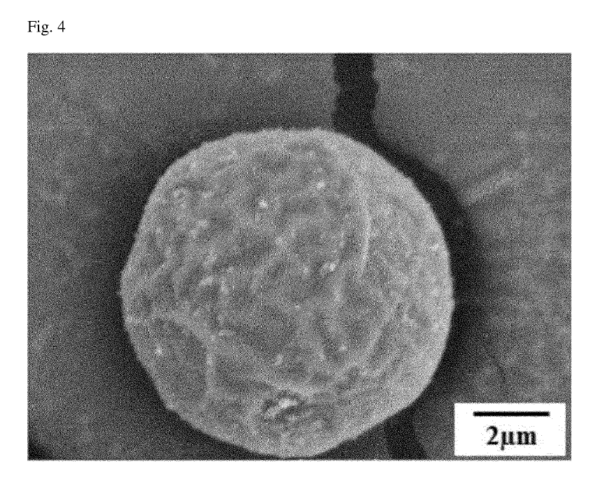

FIG. 3 provides an SEM image of poly(methyl methacrylate) (PMMA) beads used in an exemplary embodiment and an image of the PMMA bead powder, and FIG. 4 is a magnified view of the SEM image of FIG. 3.

After three hours of stirring, the alcohol-based solvent, isopropyl alcohol, was evaporated by drying in a 80° C. vacuum oven for about three hours, and PMMA beads, whose surfaces are coated with the tellurium nanowires (i.e. the tellurium nanowires are adsorbed onto a surface of the PMMA beads) due to a difference in surface charge, were obtained.

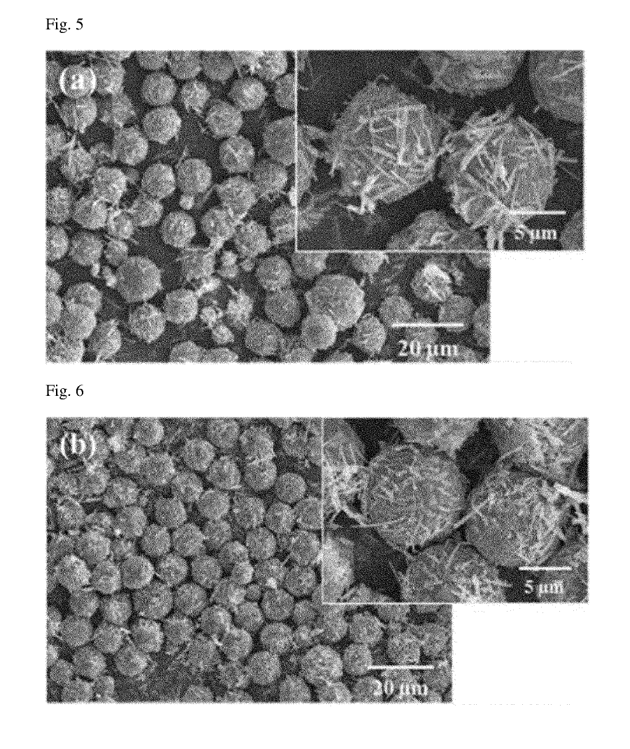

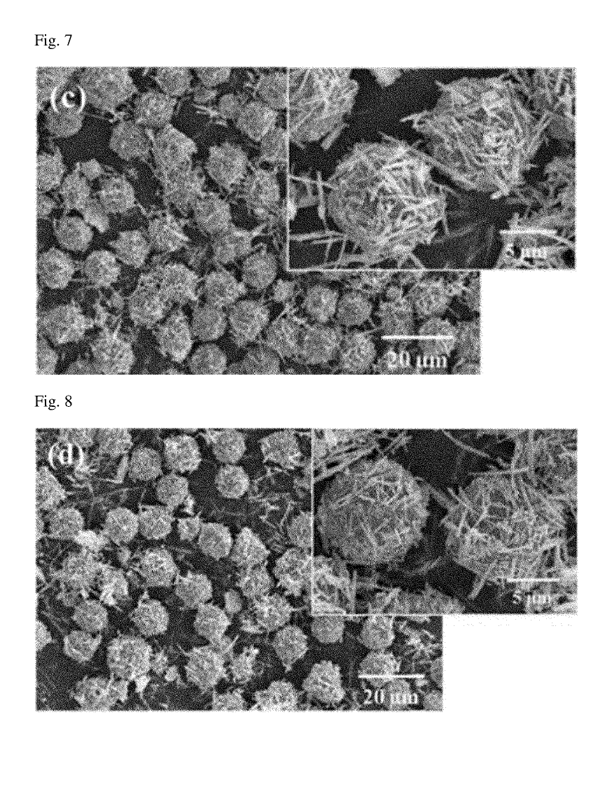

FIGS. 5 to 8 are SEM images of PMMA beads onto which tellurium nanowires are adsorbed, wherein the tellurium nanowire content is 28.5 wt % (6.95 vol %) for FIG. 5, 37.5 wt % (10.11 vol %) for FIG. 6, 44.4 wt % (13.02 vol %) for FIG. 7, and 50 wt % (15.78 vol %) for FIG. 8.

According to FIGS. 5 to 8, as the tellurium nanowire content increases, more tellurium nanowires adsorb onto a surface of the PMMA beads.

PMMA beads, onto which tellurium nanowires are adsorbed, were shaped for 30 minutes at 150° C. and 400 MPa by hot pressing to prepare a thermoelectric composite.

For comparison with the thermoelectric composite in terms of a cross-sectional structure, electrical characteristics, and the like, a sample was prepared only of tellurium nanowires. The sample consisting only of tellurium nanowires was prepared by shaping tellurium nanowires for 30 minutes at 150° C. and 400 MPa by hot pressing.

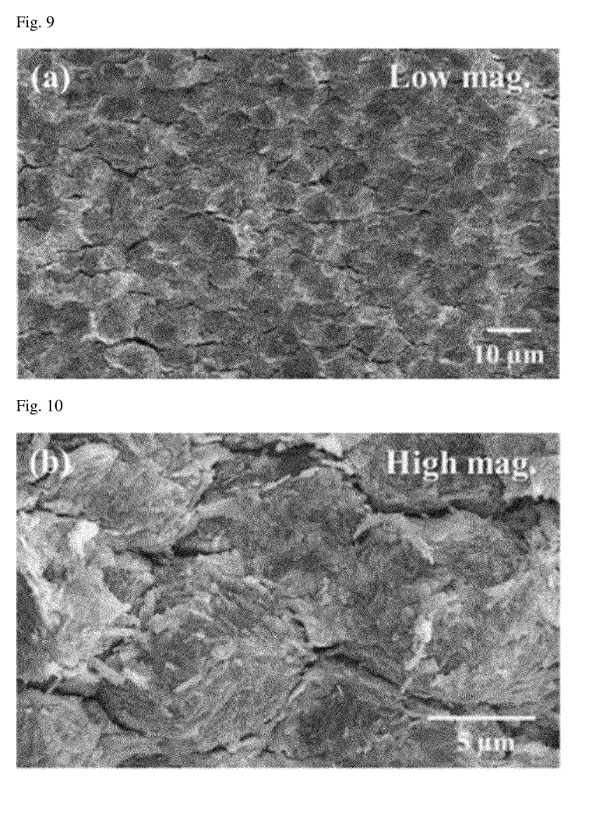

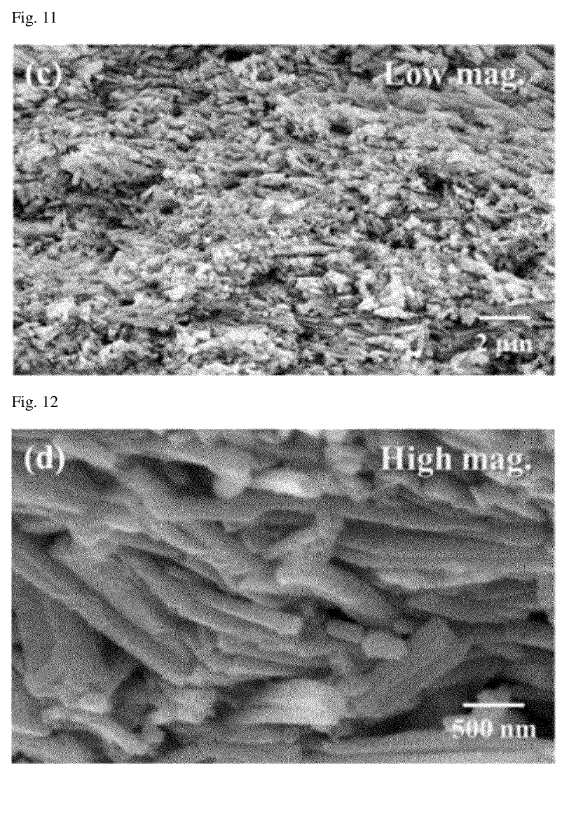

FIGS. 9 and 10 are cross-sectional SEM images of a thermoelectric composite prepared according to an exemplary embodiment, and FIGS. 11 and 12 are cross-sectional SEM images of a sample shaped out of only tellurium nanowires.

According to FIGS. 9 to 12, tellurium nanowires are uniformly adsorbed onto a surface of PMMA beads, which are media in the thermoelectric composites. Also, the PMMA beads attained an angular shape due to a high pressure and heat that had been applied during hot pressing. As a result, the porosity among the thermoplastic polymer beads (particles) decreased and the density increased, causing a packing density of the thermoelectric composite to increase.

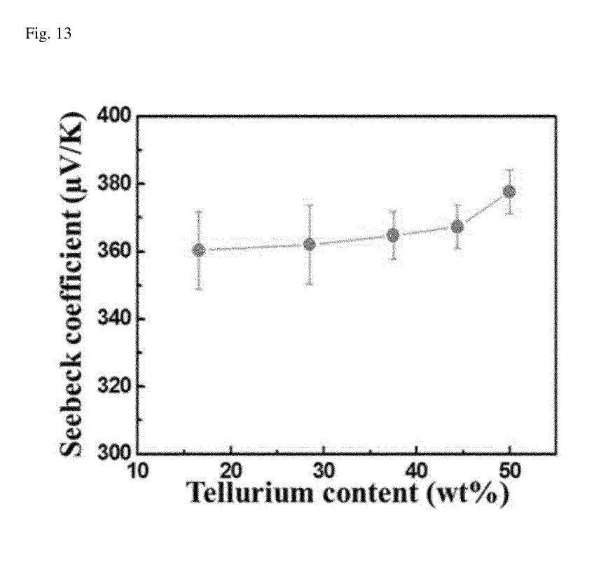

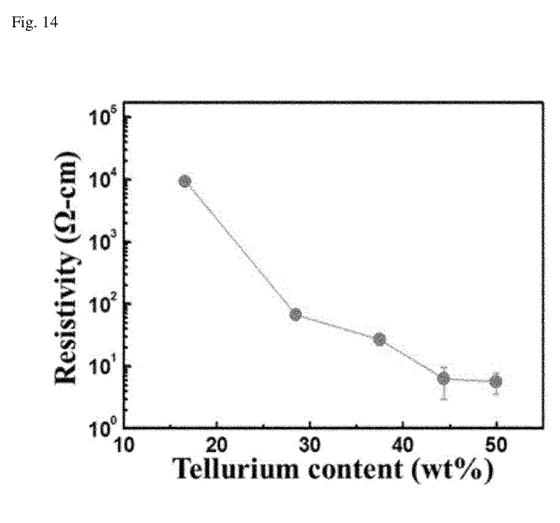

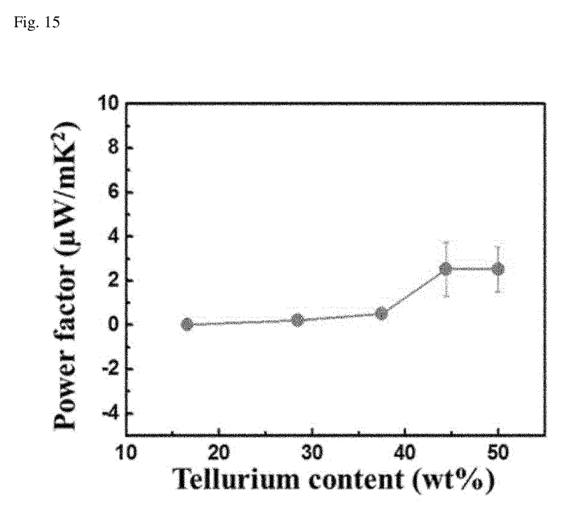

Thermoelectric characteristics of the thermoelectric composites prepared according to exemplary embodiments of the present invention were evaluated. FIG. 13 is a graph showing Seebeck coefficients of thermoelectric composites according to tellurium nanowire content, wherein the thermoelectric composites were prepared according to an exemplary embodiment, and FIG. 14 is a graph showing resistivities of thermoelectric composites according to tellurium nanowire content, wherein the thermoelectric composites were prepared according to an exemplary embodiment.

According to FIGS. 13 and 14, the thermoelectric composites prepared according to exemplary embodiments of the present invention exhibited a high Seebeck coefficient of 350 μV/K or more in all cases, and resistivity decreased with an increasing tellurium nanowire content. Such results come from the conductive nature of the tellurium nanowire.

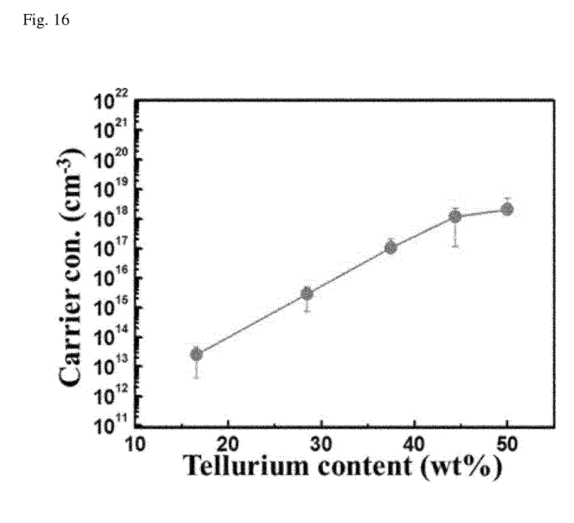

FIG. 15 is a graph showing power factors of thermoelectric composites according to tellurium nanowire content, wherein the thermoelectric composites were prepared according to an exemplary embodiment, and FIG. 16 is a graph showing carrier concentrations of thermoelectric composites according to tellurium nanowire content, wherein the thermoelectric composites were prepared according to an exemplary embodiment.

According to FIGS. 15 and 16, the power factor and carrier concentration of the thermoelectric composites prepared according to exemplary embodiments of the present invention increased with increased tellurium nanowire content.

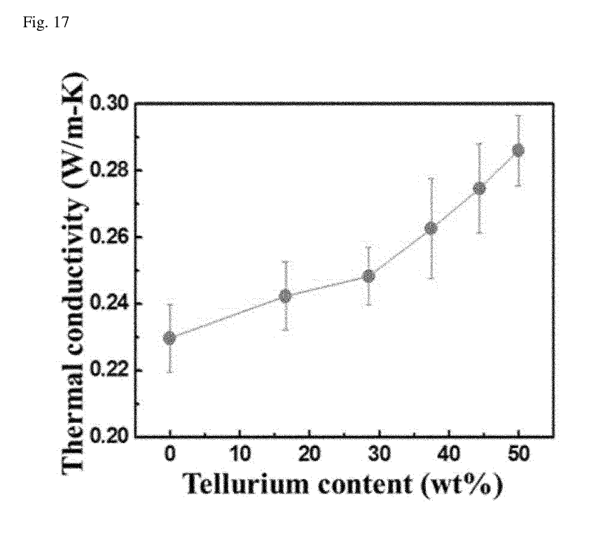

FIG. 17 is a graph showing thermal conductivitities of thermoelectric composites prepared according to an exemplary embodiment.

According to FIG. 17, the thermal conductivities were measured using a heat flow method. The results showed that the thermal conductivity of the thermoelectric composites prepared according to exemplary embodiments of the present invention increased with increased tellurium nanowire content, but not by a considerable amount compared to the thermal conductivity of the original polymer. Such results show that the thermoelectric composites have excellent heat insulating properties.

As described above, while the present invention has been described with reference to specific embodiments, the present invention is not limited thereto. It should be clear to those skilled in the art that various modifications and alterations may be made without departing from the spirit and scope of the present invention.

### INDUSTRIAL APPLICABILITY

The thermoelectric composite according to the present invention has a thermoelectric characteristic, electrical conductivity, and heat insulating properties, can be used in fields of materials for heat control components, thermoelectric materials, and the like, and is industrially applicable.

1. A thermoelectric composite comprising: a matrix comprising thermoplastic polymer particles, and electroconductive material selected from the group consisting of a chalcogen and a chalcogenide are dispersed at grain boundaries between the thermoplastic polymer particles to form conductive pathways,
wherein an average size of the electroconductive material is smaller than an average size of the thermoplastic polymer particles, the chalcogen selected from the group consisting of sulfur (S), selenium (Se), tellurium (Te), and polonium (Po) and combinations thereof, the chalcogenide comprising a chalcogen selected from the group consisting of S, Se, Te, Po and combinations thereof, and the thermoelectric composite has a thermal conductivity of 0.1 to 0.5 W/m·K.

2. The thermoelectric composite according to claim 1, wherein the electroconductive material and beads of the thermoplastic polymer are in a volume ratio of 1:3˜30.

3. The thermoelectric composite according to claim 1, wherein the thermoplastic polymer particles comprise a material selected from the group consisting of poly(methyl methacrylate), polyamide, polypropylene, polyester, poly(vinyl chloride), polycarbonate, polyphthalamide, polybutadiene terephthalate, polyethylene terephthalate, polyethylene, polyether ether ketone, polystyrene and combinations thereof, and has an average size of 100 nm to 100 μm.

4. The thermoelectric composite according to claim 1, wherein the chalcogenide are selected from the group consisting of CdS, Bi₂Se₃, PbSe, CdSe, PbTeSe, Bi₂Te₃, Sb₂Te₃, PbTe, CdTe, ZnTe, La₃Te₄, AgSbTe₂, Ag₂Te, AgPb₁₈BiTe₂₀, (GeTe)ₓ(AgSbTe₂)₁₋ₓ (x is a real number smaller than 1), AgₓPb₁₈SbTe₂₀ (x is a real number smaller than 1), AgₓPb_{22.5}SbTe₂₀ (x is a real number smaller than 1), SbₓTe₂₀ (x is a real number smaller than 1), BiₓSb₂₋ₓTe₃ (x is a real number smaller than 2) and combinations thereof.

5. The thermoelectric composite according to claim 1, wherein the electroconductive material is a nanowire, a nanorod, a nanotube, or a fragment.

6. A method of preparing a thermoelectric composite, the method comprising:
preparing an electroconductive material selected from the group consisting of at least one chalcogen and at least one chalcogenide;
mixing the electroconductive material and thermoplastic polymer beads in a solvent;
adsorbing the electroconductive material onto a surface of the thermoplastic polymer beads by using a difference in surface charge, and drying a mixture of the electroconductive material and the thermoplastic polymer beads to remove the solvent; and
shaping the thermoplastic polymer beads, onto which the electroconductive materials adsorbed, by a hot pressing method to prepare the thermoelectric composite that contains a conductive pathway formed by the electroconductive materials dispersed at grain boundaries between the thermoplastic polymer beads,
wherein an average size of the electroconductive material is smaller than an average size of the thermoplastic polymer particles, the chalcogen selected from the group consisting of S, Se, Te, Po and combinations thereof, the chalcogenide comprising a chalcogen selected from the group consisting of S, Se, Te, Po and combinations thereof, and the thermoelectric composite has a thermal conductivity of 0.1 to 0.5 W/m·K.

7. The method according to claim 6, wherein the process of shaping is performed under a pressure of 10 to 1000 MPa and in a range of temperatures greater than or equal to a glass transition temperature of the thermoplastic polymer beads and, at the same time, less than a melting temperature of the thermoplastic polymer beads so that a contact interface between the thermoplastic polymer beads increases.

8. The method according to claim 6, wherein the electroconductive materials and the thermoplastic polymer beads are mixed in a volume ratio of 1:3˜30.

9. The method according to claim 6, wherein thermoplastic polymer beads contain a material selected from the group consisting of poly(methyl methacrylate), polyamide, polypropylene, polyester, poly(vinyl chloride), polycarbonate, polyphthalamide, polybutadiene terephthalate, polyethylene terephthalate, polyethylene, polyether ether ketone, polystyrene and combinations thereof, and have an average size of 100 nm to 100 μm.

10. The method according to claim 6, wherein the chalcogenide is selected from the group consisting of CdS, Bi₂Se₃, PbSe, CdSe, PbTeSe, Bi₂Te₃, Sb₂Te₃, PbTe, CdTe, ZnTe, La₃Te₄, AgSbTe₂, Ag₂Te, AgPb₁₈BiTe₂₀, (GeTe)ₓ(AgSbTe₂)₁₋ₓ (x is a real number smaller than 1), AgₓPb₁₈SbTe₂₀ (x is a real number smaller than 1), AgₓPb_{22.5}SbTe₂₀ (x is a real number smaller than 1), SbₓTe₂₀ (x is a real number smaller than 1), BiₓSb₂₋ₓTe₃ (x is a real number smaller than 2) and combinations thereof.

11. The method according to claim 6, wherein the electroconductive materials are a nanowire, a nanorod, a nanotube, or a fragment.

12. The method according to claim 6, wherein the process of preparing the electroconductive material include:
dissolving at least one oxide in a solvent;
adding a reducing agent to the solvent and then stirring; and
drying the stirred oxide and reducing agent to obtain at least one electroconductive material selected from the group consisting of a chalcogen and chalcogenide.

13. The method according to claim 12, wherein the reducing agent is selected from the group consisting of hydroxylamine, pyrrole, poly(vinylpyrrolidone), polyethylene glycol, hydrazine hydrate, hydrazine monohydrate, ascorbic acid and combinations thereof.

14. The method according to claim 12, wherein the solvent is selected from the group consisting of ethylene glycol, diethylene glycol, sodium dodecylbenzenesulfonate, NaBH₄ and combinations thereof.
